(19) United States
(12) Patent Application Publication
(10) Pub. No.: US 2024/0071819 A1
(43) Pub. Date: Feb. 29, 2024

(54) STRESS MITIGATION FOR THREE-DIMENSIONAL METAL CONTACTS

(71) Applicant: Micron Technology, Inc., Boise, ID (US)

(72) Inventors: Chandra S. Tiwari, Boise, ID (US); Jivaan Kishore Jhothiraman, Meridian, ID (US); Rutuparna Narulkar, Boise, ID (US); Nayan Chakravarty, Tualatin, OR (US); Pengyuan Zheng, Boise, ID (US); Hiroaki Iuchi, Boise, ID (US)

(21) Appl. No.: 18/234,111

(22) Filed: Aug. 15, 2023

Related U.S. Application Data
(60) Provisional application No. 63/402,174, filed on Aug. 30, 2022.

(51) Int. Cl. H01L 21/768; H01L 23/522

(52) U.S. Cl. CPC H01L 21/76831; H01L 23/5226; H10B 43/27

(57) ABSTRACT

A variety of applications can include apparatus having a memory device structured with a three-dimensional array of memory cells and one or more vertical metal contacts extending through levels of the memory device, where the one or more vertical metal contacts are formed with reduced stress. Each of the one or more vertical metal contacts can be constructed by forming a liner on walls of an opening in a dielectric, where the opening extends through the levels for the memory device, and forming a metal composition adjacent the liner and filling the opening with the metal composition. The liner can be removed from at least a portion of the walls of the dielectric, where the liner has a composition correlated to the metal composition such that removal of the liner reduces stress on the metal composition.

### PRIORITY APPLICATION

This application claims the benefit of priority to U.S. Provisional Application Ser. No. 63/402,174, filed Aug. 30, 2022, which is incorporated herein by reference in its entirety.

### FIELD OF THE DISCLOSURE

Embodiments of the disclosure relate generally to electronic devices and systems and, more specifically, to memory devices and formation thereof.

### BACKGROUND

Memory devices are typically provided as internal, semiconductor, integrated circuits in computers or other electronic devices. There are many different types of memory, including volatile and non-volatile memory. Volatile memory requires power to maintain its data and includes random-access memory (RAM), dynamic random-access memory (DRAM), static RAM (SRAM), and synchronous dynamic random-access memory (SDRAM) among others. Non-volatile memory can retain stored data when not powered, and includes flash memory, read-only memory (ROM), electrically erasable programmable ROM (EEPROM), erasable programmable ROM (EPROM), resistance variable memory, such as phase-change random-access memory (PCRAM), resistive random-access memory (RRAM), magnetoresistive random-access memory (MRAM), or three-dimensional (3D) XPoint™ memory, among others.

Flash memory is utilized as non-volatile memory for a wide range of electronic applications. Flash memory devices typically include one or more groups of one-transistor, floating gate or charge trap memory cells that allow for high memory densities, high reliability, and low power consumption. Two common types of flash memory array architectures include NAND and NOR architectures, named after the logic form in which the basic memory cell configuration of each is arranged. The memory cells of the memory array are typically arranged in a matrix. In an example, the gates of each floating gate memory cell in a row of the array are coupled to an access line (e.g., a word line). In a NOR architecture, the drains of each memory cell in a column of the array are coupled to a data line (e.g., a bit line). In a NAND architecture, the drains of each memory cell in a string of the array are coupled together in series, source to drain, between a source line and a data line. Memory arrays of flash memory devices are being designed as 3D structures to increase memory density. For continued increases in memory capacity, various design considerations should be implemented for enhancements to various structures within the memory device fabricated in a memory die.

### BRIEF DESCRIPTION OF THE DRAWINGS

The drawings, which are not necessarily drawn to scale, illustrate generally, by way of example, but not by way of limitation, various embodiments discussed in the present document.

FIG. 1 illustrates a block diagram of an example memory device including a memory array and associated circuits, according to various embodiments.

FIG. 2 is a block diagram of regions of an example memory device having a three-dimensional memory array in a circuit-under-array architecture, according to various embodiments.

FIG. 3 is a representation of an example three-dimensional memory device having a three-dimensional memory array with a circuit-under-array architecture, according to various embodiments.

FIGS. 4A-4D is a representation of a process flow of forming a metal contact to mitigate stress to the metal contact, according to various embodiments.

FIGS. 5A-5D is a representation of another process flow of forming a metal contact to mitigate stress to the metal contact, according to various embodiments.

FIGS. 6A-6D is a representation of another process flow of forming a metal contact to mitigate stress to the metal contact, according to various embodiments.

FIGS. 7A-7D is a representation of another process flow of forming a metal contact to mitigate stress to the metal contact, according to various embodiments.

FIG. 8 is a flow diagram of features of an example method of forming a vertical contact extending through levels of a memory device, according to various embodiments.

FIG. 9 is a flow diagram of features of another example method of forming a memory device, according to various embodiments.

FIG. 10 is a flow diagram of features of another example method of forming a vertical contact extending through levels of a memory device, according to various embodiments.

FIG. 11 is a block diagram illustrating an example of a machine in which one or more embodiments of memory devices may be implemented, according to various embodiments.

### DETAILED DESCRIPTION

The following detailed description refers to the accompanying drawings that show, by way of illustration, various embodiments that can be implemented. These embodiments are described in sufficient detail to enable those of ordinary skill in the art to practice these and other embodiments. Other embodiments may be utilized, and structural, logical, mechanical, and electrical changes may be made to these embodiments. The term “horizontal” as used in this application is defined as a plane parallel to a conventional plane or surface of a wafer or substrate, regardless of the orientation of the wafer or substrate. The term “vertical” refers to a direction substantially perpendicular to the horizontal as defined above. Various features can have a vertical component to the direction of their structure. The terms insulating and dielectric used with respect to materials refers to electrical properties of the respective materials. The various embodiments are not necessarily mutually exclusive, as some embodiments can be combined with one or more other embodiments to form new embodiments. The following detailed description is, therefore, not to be taken in a limiting sense.

In conventional processing of metal contacts within 3D memory devices, the metal contacts can experience stress with respect to the dielectric walls to which the metal contacts are formed. Such stress can be to a high enough level that contributes to weakness of the metal contacts or associated structural components. For example, cracks in vertical slits in which the metal contacts are located can occur due, at least in part, to the stress. Such stress can contribute to cracking of an oxide to which the metal contact is formed. Such stress can also contribute to bending of metal contacts that are vertically formed. In addtion, the bending of the metal contacts in a 3D memory device can cause bending of pillars of the memory array in proximity to the metal contacts. Further, with the tops of the metal contacts displaced from a vertical axis through the bottom of the metal contact, alignment with other conductive structures above the level of the memory array can be affected, causing additional steps in processing to make the connections of the metal contacts to the upper conductive structures.

In various embodiments, a substantially stressless flow can be implemented to mitigate the above issues with forming metal contacts in a memory device as well as lower parasitic capacitance with access lines to the memory array of a memory device. After levels of dielectric regions are formed for tiers in a memory device being fabricated and after forming an opening having dielectric side walls, a liner can be deposited on the dielectric side walls. The liner can be non-conformal in that the liner can be formed without being continuously uniform in thickness along the dielectric side walls. The liner can be formed such that the liner is not formed at the bottom level of the opening, to or through which the metal contact is to be formed. Alternatively, the liner can be formed to the bottom level of the metal contact including across the opening at the bottom of the opening where the metal contact is to be formed to contact metallizations at a level below the memory array. The liner across the opening at the bottom of the opening can be removed (punched) to allow material for the metal contact to form across this opening. In addition, an ex-situ or in-situ clean can be used to remove any small amount deposited at the bottom level. The material of the liner can be, but is not limited to, carbon, carbon with a precentage of boron, or carbon with a percentage of a metal. The precentage of boron and the percentage of a metal can be in the range of 1% to 10% or less.

After forming the liner on the dielectric walls of the opening, a metal can be formed filing the liner and any of the opening beyond the liner. The metal formed through the bottom of the opening can connect to a titantium nitride (TiN) region or tungsten silicide (WSix) region of a complementary metal oxide semiconductor (CMOS) device in a region below the bottom level of the memory array of the memory device being formed. The formed metal can be polished and can include one or more metal regions. A film of Ti, TiN, and W can be deposited as the metal. The Ti and TiN can be formed as a metal barrier for W as the primary metal of the metal contact, where the metal barrier can be implemented as an adhesion region. The material for the liner and the material selected for the metal contact can be selected such that the metal can delaminate from the liner, reducing stress on the metal. The liner can be removed, for example but not limited to, using a resist strip process. For a carbon liner, for example, the carbon liner can be subjected to an oxygen-based dry plasma. Other removal processes can include oxygen and amnonia dry plasma or use of a hydrogen forming gas.

Removing the liner can create a free metal structure in that the material of the contact becomes relaxed with respect to stress. The amount of stress relief can depend on the amount of the length of the opening that is covered by the liner. The amount of stress relief is a function of the percent of the length of the liner along the opening with the largest amount of stress relief being for the liner formed completely along the opening with the lesser amounts of stress relief for smaller portions of the length of the opening covered with the liner. The thickness of the liner can vary from a largest thickness at the top of the opening for the metal contact to a lowest thickness at the end of the liner nearest the end of the opening. For a carbon liner, the thickness can range from about 10 nm to about 3 nm and in some embodiments can range from monolayers to a monolayer of carbon. In addition, the carbon liner can have a varying composition with essentially carbon at the top of the opening to carbon with a percentage of other materials incorporated in the carbon at the end of the liner near the bottom of the opening. In some embodiments, a liner, such as but not limited to a carbon liner, can be left in the structure for the metal contact, where leaving the liner may lead to creating one or more relatively small air gaps by the metal contact delaminating from the liner. After forming the metal contact, a dielectric material, such as but not limited to silicon oxide, can be formed covering the top of the metal contact. The dielectric material formed covering the top of the metal contact can be non-conformal or semi-conformal.

The memory array of a 3D memory device can extend in a horizontal plane along a substrate, which can be designated as a x-y plane, and in a vertical direction, taken as the z direction perpendicular to the x-y plane. Design considerations can be implemented with the 3D memory arrays such as using a circuit-under-array (CuA) architecture to enhance reduction of die size or increase utilization of space in a die. CuA refers generally to circuitry located in a memory die under a memory array of the memory die. The CuA can include control logic and sensing circuitry for sensing the programmed data states of memory cells of the memory array. With the control logic and sensing circuitry fabricated below the memory array, using semiconductor processing that can include CMOS processing technology, CuA can be referred to as CMOS under array.

For a 3D NAND memory array, which can include vertical strings of memory cells, using floating gate transistors or charge trap transistors, and connections from data lines positioned above the 3D NAND, vertical connections extending through the 3D NAND memory array or through memory breaks within the 3D NAND memory array can be used to couple to sensing circuitry and other control logic of the CuA for the memory array. A CuA architecture, which allows for circuits that operate with a 3D memory array to be structured in a space in the substrate below the 3D memory array, provides capabilities for higher densities of memory cells. These capabilities address a desire to limit increases in the area (horizontal plane) of the memory die. For continued increases in memory capacity, other design considerations can be implemented that also provide for enhancements to reduction of parasitic structures in operation of the memory device.

Various memory device formats can be structured in a CuA architecture, such as but not limited to NOR or NAND architecture semiconductor memory arrays. Both NOR and NAND flash architecture semiconductor memory arrays are accessed through decoders that activate specific memory cells by selecting the access line coupled to their gates. In a NOR architecture semiconductor memory array, once activated, the selected memory cells place their data values on data lines, causing different currents to flow depending on the state at which a particular cell is programmed. In a NAND architecture semiconductor memory array, a relatively high bias voltage is applied to a drain-side select gate (SGD) line. Access lines coupled to the gates of the unselected memory cells of each group are driven at a specified pass voltage (e.g., Vpass) to operate the unselected memory cells of each group as pass transistors (e.g., to pass current in a manner unrestricted by their stored data values). Current then flows between the source line and the data line through each series-coupled group, restricted only by the selected memory cells of each group, placing current encoded data values of selected memory cells on the data lines.

Each flash memory cell in a NOR or NAND architecture semiconductor memory array can be programmed individually or collectively to one or a number of programmed states. For example, a single-level cell (SLC) can represent one of two programmed states (e.g., 1 or 0), representing one bit of data. Flash memory cells can also represent more than two programmed states, allowing the manufacture of higher density memories without increasing the number of memory cells, as each cell can represent more than one binary digit (e.g., more than one bit). Such cells can be referred to as multi-state memory cells, multi-digit cells, or multi-level cells (MLCs). In certain examples, MLC can refer to a memory cell that can store two bits of data per cell (e.g., one of four programmed states), a triple-level cell (TLC) can refer to a memory cell that can store three bits of data per cell (e.g., one of eight programmed states), and a quad-level cell (QLC) can store four bits of data per cell. MLC is used herein in its broader context to refer to any memory cell(s) that can store more than one bit of data per cell (i.e., that can represent more than two programmed states). The sensing and control circuitry for such NOR or NAND architecture semiconductor memory arrays can be structured beneath the respective memory array in a CuA architecture.

In a CuA architecture for a memory die having a 3D memory array, the CuA region can include circuits for controlling the operation of the 3D memory array. One or more control circuits of the CuA can provide control signals to the 3D memory array in order to perform a read operation or a write operation on the 3D memory array. The CuA can include one or more of control circuitry, state machines, decoders, sense amplifiers, read/write circuits, and controllers. These circuits can implement one or more memory array operations including erasing, programming, or reading operations. For example, the CuA region can include an on-chip memory controller for determining row and column address, access line and data line addresses, memory array enable signals, and data latching signals. The operations on the 3D memory array are typically performed to access one or more memory cells in response to requests from other circuits on the memory die or a device external to the memory die. The CuA region can include pad structures to couple the memory array or one or more circuits in the CuA region to other portions of the die of the memory device, or to couple to devices external to the memory device.

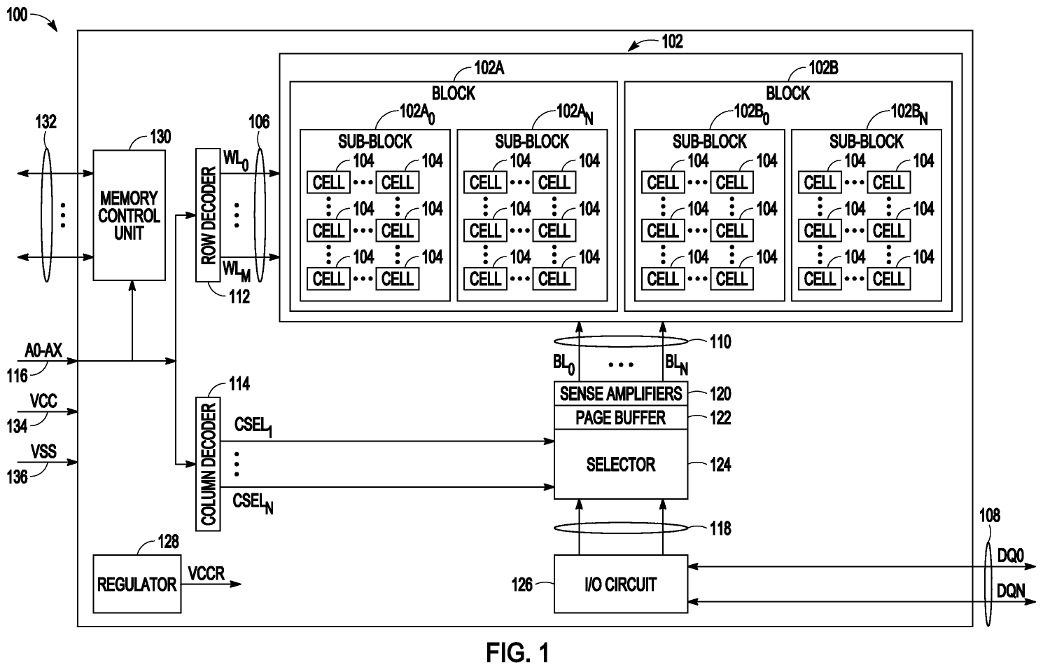

FIG. 1 illustrates a block diagram of various components of an embodiment of an example memory device 100 including a memory array 102 and associated circuits. Example memory device 100 includes a plurality of memory cells 104, and one or more circuits or components to provide communication with, or perform one or more memory operations on, the memory array 102. The memory device 100 can include a row decoder 112, a column decoder 114, sense amplifiers 120, a page buffer 122, a selector 124, an I/O circuit 126, and a memory control unit 130. In various embodiments, the memory device 100 can be structured with a CuA architecture. Control circuitry for the memory array 102 can be located in a CuA region below the memory array 102 in the CuA architecture.

The memory cells 104 of the memory array 102 can be arranged in blocks, such as first and second blocks 102A, 102B. Each block can include sub-blocks. For example, the first block 102A can include first and second sub-blocks 102A₀, 102Aₙ, and the second block 102B can include first and second sub-blocks 102B₀, 102Bₙ. Each sub-block can include a number of physical pages, with each page including a number of memory cells 104. Although illustrated herein as having two blocks, with each block having two sub-blocks, and each sub-block having a number of memory cells 104, in other examples, the memory array 102 can include more or fewer blocks, sub-blocks, memory cells, etc. In other examples, the memory cells 104 can be arranged in a number of rows, columns, pages, sub-blocks, blocks, etc., and accessed using, for example, access lines 106, first data lines 110, or one or more select gates, source lines, etc.

The memory control unit 130 can control memory operations of the memory device 100 according to one or more signals or instructions received on control lines 132, including, for example, one or more clock signals or control signals that indicate a desired operation (e.g., write, read, erase, etc.), or address signals (AO-AX) received on one or more address lines 116. One or more devices external to the memory device 100 can control the values of the control signals on the control lines 132 or the address signals on the address lines 116. Examples of devices external to the memory device 100 can include, but are not limited to, a host, a memory controller, a processor, or one or more circuits or components not illustrated in FIG. 1.

The memory device 100 can use access lines 106 and first data lines 110 to transfer data to (e.g., write or erase) or from (e.g., read) one or more of the memory cells 104. The row decoder 112 and the column decoder 114 can receive and decode the address signals (AO-AX) from the address lines 116, can determine which of the memory cells 104 are to be accessed, and can provide signals to one or more of the access lines 106 (e.g., one or more of a plurality of access lines (WLO-WLm)) or the first data lines 110 (e.g., one or more of a plurality of data lines (BLO-BLn)), such as described above.

The memory device 100 can include sense circuitry, such as the sense amplifiers 120, configured to determine the values of data on (e.g., read), or to determine the values of data to be written to, the memory cells 104 using the first data lines 110. For example, in a selected string of memory cells 104, one or more of the sense amplifiers 120 can read a logic level in the selected memory cell 104 in response to a read current flowing in the memory array 102 through the selected string to the first data lines 110. Sense amplifiers 120 can include CMOS devices coupled to 3D metal contacts formed in a configuration providing stress mitigation for the 3D metal contacts.

One or more devices external to the memory device 100 can communicate with the memory device 100 using the I/O lines (DQO-DQN) 108, address lines 116 (AO-AX), or control lines 132. The I/O circuit 126 can transfer values of data in or out of the memory device 100, such as in or out of the page buffer 122 or the memory array 102, using the I/O lines 108, according to, for example, the control lines 132 and address lines 116. The page buffer 122 can store data received from the one or more devices external to the memory device 100 before the data is programmed into relevant portions of the memory array 102, or can store data read from the memory array 102 before the data is transmitted to the one or more devices external to the memory device 100.

The column decoder 114 can receive and decode address signals (AO-AX) into one or more column select signals (CSEL1-CSELn). The selector 124 (e.g., a select circuit) can receive the column select signals (CSEL1-CSELn) and select data in the page buffer 122 representing values of data to be read from or to be programmed into memory cells 104. Selected data can be transferred between the page buffer 122 and the I/O circuit 126 using second data lines 118. The memory control unit 130 can receive positive and negative supply signals, such as a supply voltage (VCCx) 134 and a negative supply (VSS) 136 (e.g., a ground potential), from an external source or supply (e.g., an internal or external battery, an AC-to-DC converter, etc.). In certain examples, the memory control unit 130 can include a regulator 128 to internally provide positive or negative supply signals.

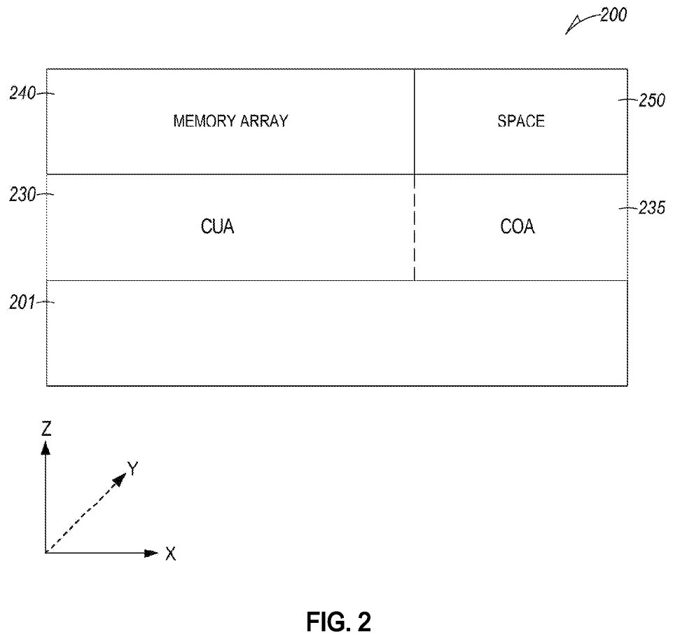

FIG. 2 is a block diagram of regions of an embodiment of an example memory device 200 having a 3D memory array, in which the regions are shown in the z-x plane. A memory array region 240 having horizontal planes (x-y) of memory cells is disposed vertically over a CuA region 230 disposed in a substrate 201. The horizontal planes (x-y) of memory cells can be structured as multiple arranged tiers comprising memory cells. The CuA region 230 can include control circuitry for the memory array of the memory array region 240. The control circuitry in the CuA region 230 can include one or more instrumentalities similar to row decoder 112, column decoder 114, sense amplifiers 120, page buffer 122, selector 124, I/O circuit 126, and memory control unit 130 of memory device 100 shown in FIG. 1. A space 250 can be implemented adjacent the memory array region 240 and above the CuA region 230. The space 250 can be implemented beyond the horizontal extent of the memory array and may not directly contain elements of the control and sensing circuitry for the memory array, which can be located in the CuA region 230. The CuA region 230 can include a space of the CuA located directly below the 3D memory array of memory array region 240 such that this space of the CuA extends at least in one direction in the x-y plane to the same extent as the 3D memory array extends in this direction. The CuA region 230 can include a region in the die outside of the horizontal extent of the 3D memory array, referred to as OA, and below a bottom level of the 3D memory array. In various embodiments, circuits or contacts can be structured outside the horizontal extent of and below a level of the 3D memory array. The circuits in this OA region can be referred to as circuits-outside-array, CoA, in a CoA region 235. The space of the CoA can be disposed adjacent the portion of the space of the CuA region 230 that contains control circuitry for the memory array of the memory array region 240 and below the level of the 3D memory array. In various embodiments, CMOS devices can be located in CuA region 230 or CoA region 235 and can be coupled to 3D metal contacts formed in a configuration providing stress mitigation for the 3D metal contacts. In memory devices without a CuA architecture, CMOS devices can be located in a periphery to a memory array and coupled to the memory array. Such a periphery can be located similar to space 250.

With the memory device 200 having a CoA region 235 adjacent the CuA region 230 containing control circuitry for the memory array and placed below a level of the memory array in memory array region 240, the space 250 can be arranged directly over the CoA region 235. The CoA region 235 can include pads to couple to nodes for external connections or pins of the package for the memory device 200. The space 250 can also be implemented with conductive columns to couple to the top levels of the memory device 200.

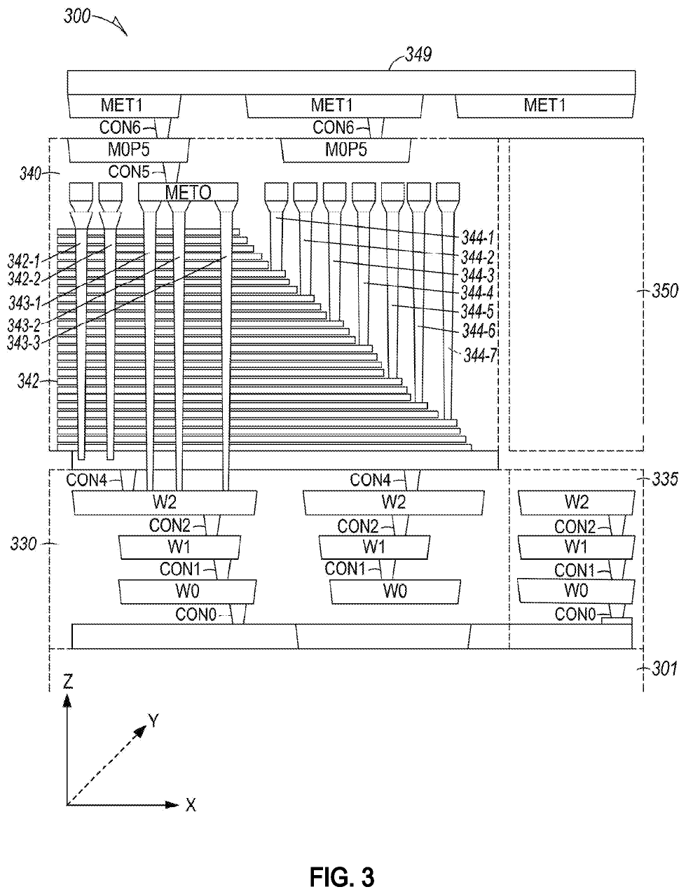

FIG. 3 is a representation of an embodiment of an example memory device 300 having a 3D memory array, in which the regions are shown in a vertical cross-section in the z-x plane. Memory device 300 can be a 3D NAND memory device. A memory array region 340 having horizontal planes (x-y) of memory cells is disposed vertically over a CuA region 330 disposed in a substrate 301. The horizontal planes (x-y) of memory cells are structured as multiple arranged tiers 342 comprising memory cells. CuA region 330 can include control circuitry for the memory array of memory array region 340. The control circuitry can include one or more instrumentalities similar to row decoder 112, column decoder 114, sense amplifiers 120, page buffer 122, selector 124, I/O circuit 126, and memory control unit 130 of memory device 100 of FIG. 1 or other circuits to control access to selected memory cells of tiers 342. A space 350, similar to space 250 of FIG. 2, can be adjacent memory array region 340 and above CuA region 330. Memory device 300 can have a CoA region 335, as part of CuA region 330, adjacent the section of CuA region 330 where CuA region 330 contains the control circuitry and sensing of the memory array in memory array region 340, and below a level of the memory array in memory array region 340. Space 350 can be arranged directly over CoA region 335. CoA region 335 can include pads to couple to nodes for external connections or pins of the package for memory device 300. Space 350 can also be implemented with conductive columns to couple to the top levels of memory device 300.

FIG. 3 also illustrates some of the elements of a memory device 300 having a 3D memory array. The memory device can be a NAND memory device. For discussion purposes, a small number of structural elements are shown in FIG. 3. Memory cells of tiers 342 can extend from pillars such as pillars 342-1 and 342-2. Though only two such pillars are shown, other such pillars are located with respect to tiers 342. Memory device 300 can also include, but is not limited in number to, thru-vias 344-1 . . . 344-7 along with conductive contacts 343-1, 343-2, and 343-3. Pillars 342-1 and 342-2 for memory cells, thru-vias 344-1 . . . 344-7, and the conductive contacts 343-1, 343-2, and 343-3 can extend above and below tiers 342 and can contact different metallization levels, which can be at various vertical locations in the structure of the 3D memory array of the memory array region 340, such that access to the memory cells in the tiers 342 can be attained by a device external to the 3D memory array. Pillars 342-1 and 342-2, thru-vias 344-1 . . . 344-7, and conductive contacts 343-1, 343-2, and 343-3, and other similar structures provide vertical connections extending through the 3D memory array or through memory breaks within the 3D memory array, which vertical connections can be used to couple to sensing circuitry and other control logic of CuA region 330 for the 3D memory array.

As a non-limiting example, FIG. 3 shows two metal layers labelled W2, two metal layers labelled W1, and two metal layers labelled W0 in the CuA region 330, where these metal layers provide electrical connections with circuit elements in the CuA region 330. In some embodiments, metal layers may be replaced with conductively doped semiconductor material, such as but not limited to conductively doped polysilicon. Electrical connections between metal layers or conductive semiconductor layers at different vertical levels in the CuA region 330 can be provided by conductive contact vias labelled CON0, CON1, CON2, and CON4. Similarly, the CoA region 335 can include metal layers labelled W2, W1, and W0 to provide electrical connections with circuit elements in the CoA region 335.

At the top of the memory region 340 are metal layers labelled MOPS, which metal layers can interface with another metallization layer labelled MET1. MET1 can be top metallizations for the die containing the memory device 300 and can be covered by a passivation layer 349. The passivation layer 349 is an insulating layer and can include one or more materials such as, but not limited to, tetraethyl orthosilicate (TEOS) and an oxynitride. The oxynitride, for example, can include silicon oxynitride. The various MOPS layers can couple to various MET1 layers by different contact vias CON6 and can couple to the thru-vias 344-1 . . . 344-7 in the memory array region 340.

Thru-vias 344-1 . . . 344-7, which are vias providing conductive paths through the vias in the memory array region 340, can be long vias, relative to the thru-vias CONO, CON1, CON2, CON4, CON5, and CON6. The conductive portions of thru-vias 344-1 . . . 344-7 can couple to metal layers W2 in the CuA region 330. Other such relatively long structures such as conductive contacts 343-1, 343-2, and 343-3, which can be referred to as CON3 metal, can also terminate in a different metal layer MET0.

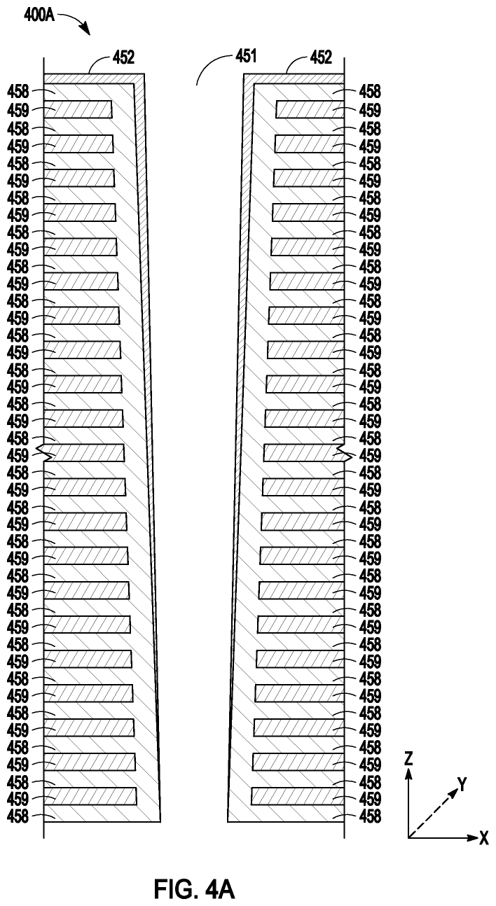

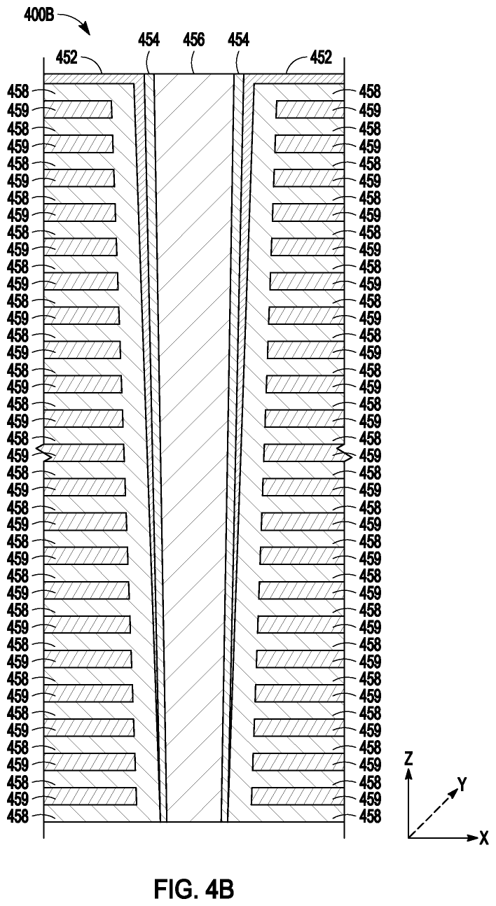

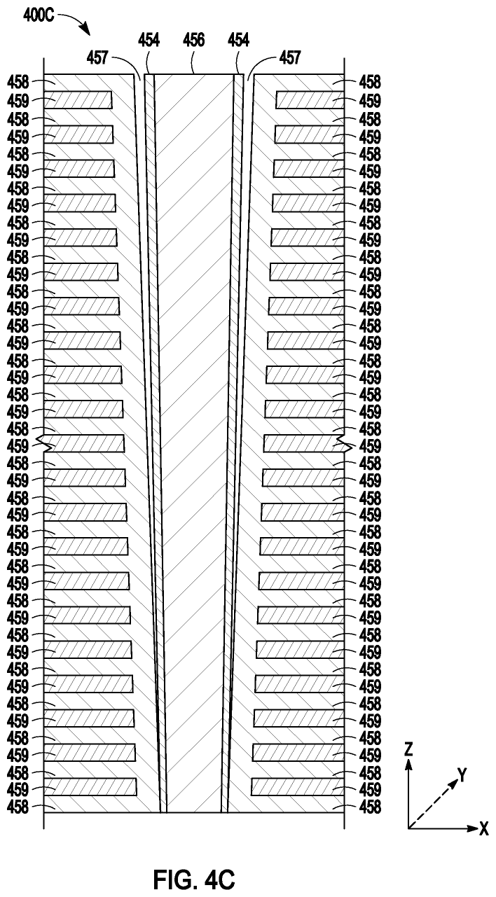

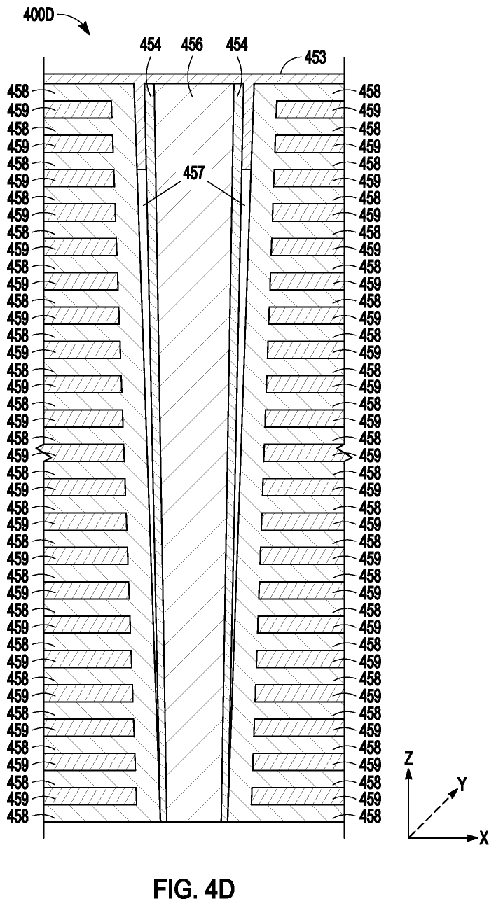

FIGS. 4A-4D is a representation of an embodiment of an example process flow of forming a metal contact in formation of a memory device, where the process flow is implemented to mitigate stress to the metal contact. FIG. 4A shows a structure 400A after an opening 451 has been formed in a region of alternating dielectric regions 459 and 458 in a vertical direction in fabrication of a memory device. The alternating dielectric regions 459 can be constructed as multiple dielectric regions 459, where the individual dielectric regions 459 of the multiple dielectric regions 459 are formed in parallel separated from each other by a dielectric region 458. Dielectric regions 459 form different levels in a vertical direction of structure 400A. In forming opening 451, the horizontal length of each individual dielectric region 459 can be larger than the horizontal lengths of dielectric region 459 above the individual dielectric region 459. The material of dielectric region 458 in structure 400A can be formed as walls of the opening 451. Alternatively, a material different from dielectric region 458 can be used to form the walls of opening 451. Dielectric regions 459 can be nitride regions, where the nitride can be, but is not limited to, silicon nitride. Dielectric regions 459 can be oxide regions, where the oxide can be, but is not limited to, silicon oxide.

A liner 452 has been formed on the walls of opening 451 in the dielectric defined by dielectric regions 458 and 459. Opening 451 extends through the levels, reflected in dielectric regions 459, for the memory device being fabricated. Liner 452 extends from a level at the top of opening 451 at least partially along the walls of opening 451. Liner 452 can be formed on the walls of opening 451 such that liner 452 does not extend to the bottom of opening 451 that is to be the bottom of the vertical metal contact being formed. The bottom of opening 451 is on a structure of the memory device being formed. An ex-situ or in-situ cleaning procedure can be used to remove any small amount at the bottom of opening 451 formed in the formation of liner 452. Liner 452 can be a carbon liner. The carbon liner can be formed using a deposition process appropriate for forming a carbon liner to meet the structural dimensions for forming liner 452 in opening 451 to form a vertical metal contact for the memory device.

FIG. 4B shows a structure 400B after processing structure 400A. A metal composition has been formed adjacent liner 452, where the metal composition fills opening 451 of structure 400A. The metal composition can include a metal barrier region 454 and a primary metal 456. Metal barrier region 454 can be formed on and contacting liner 452 and primary metal 456 can be formed on and contacting metal barrier region 454. The combination of metal barrier region 454 and primary metal 456 can extend beyond liner 452 along the wall of opening 451 of structure 400A to the bottom of opening 451 of structure 400A.

Metal barrier region 454 can be a region of one or more metallic materials. A metallic material is a composition of one or more elemental metals or a composition of two or more elements such that the composition has electrical properties of a metal. A metallic material can be structured having one or more elemental metals and one or more non-metal elements. Metal barrier region 454 can include two metallic materials. For example, the two metallic regions can include a metal element and a compound of the metal element with a non-metal, where the compound is a metallic compound. Metal barrier region 454 can include, but is not limited to, Ti formed on liner 452 and titanium nitride TiNx formed on the titanium. Primary metal 456 can be, but is not limited to, W. Materials for the metal composition of metal barrier region 454 and primary metal 456 can be formed using an appropriate process for forming the metal composition. After forming the metal composition, the surface of structure 400B has been subjected to a chemical mechanical polishing (CMP) procedure, which is a planarization process that smoothes the surface of structure 400B using a combination of chemical and mechanical actions.

FIG. 4C shows a structure 400C after processing structure 400B. Liner 452 of structure 400B has been completely removed. Complete removal may include a negligible residual amount associated with performing a complete removal of the liner. An opening 457 has been formed in the removal of liner 452. A resist strip process can be used to remove liner 452. Removing liner 452 can create a free metal structure with respect to stress, relaxing the contact material of the metal composition of metal barrier region 454 and primary metal 456. Liner 452 can have a composition correlated to the metal composition such that removal of liner 452 reduces stress on the metal composition. Liner 452 can be formed as a carbon liner with the primary metal 456 being tungsten and metal barrier region 454 being titanium and titanium nitride.

FIG. 4D shows a structure 400D after processing structure 400C. A dielectric 453 has been formed on the top of structure 400C. The deposition of dielectric 453 on the top of structure 400C can include dielectric 453 being deposited into at least a portion of opening 457, reducing the size of opening 457 of structure 400C. The material of dielectric 453 can be the same as the material of dielectric region 458. The material of dielectric 453 can be an oxide, such as but not limited to silicon oxide. The reduced opening 457 from filling at least a portion of opening 457 can be maintained as a void in structure 400D. The void is bordered by metal barrier region 454 and runs along a portion of metal barrier region 454 that is less than the length of the metal composition of metal barrier region 454 and primary metal 456. The void ends before the end of the metal composition. In a non-limiting example, the structure of the metal composition of structure 400D can be used as a metal contact in thru-vias 344-1 . . . 344-7 or conductive contacts 343-1, 343-2, and 343-3 in memory device 300 of FIG. 3 with dielectric regions 459 replaced with metal, such as W, for access lines to memory cells in pillars according to the structural architecture of memory device 300.

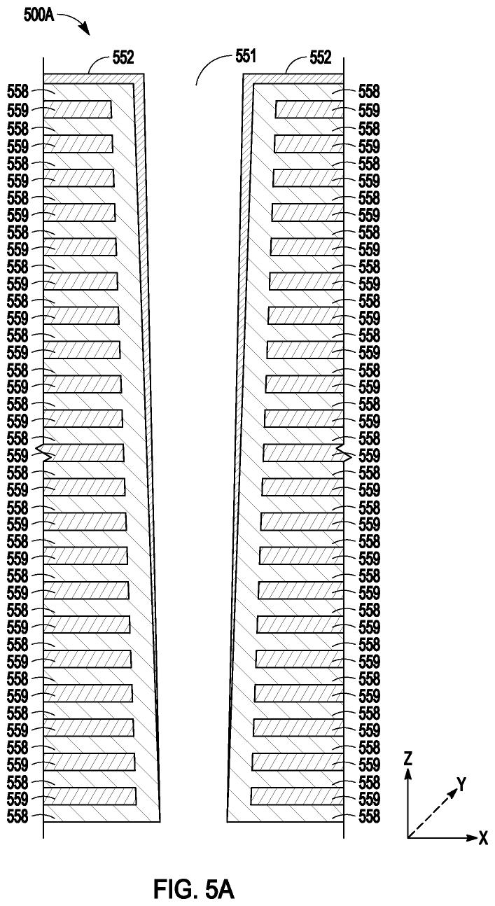

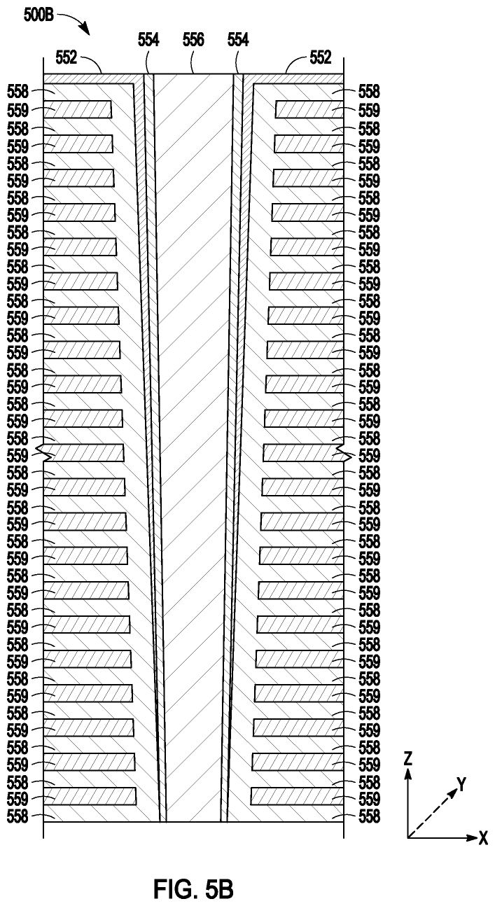

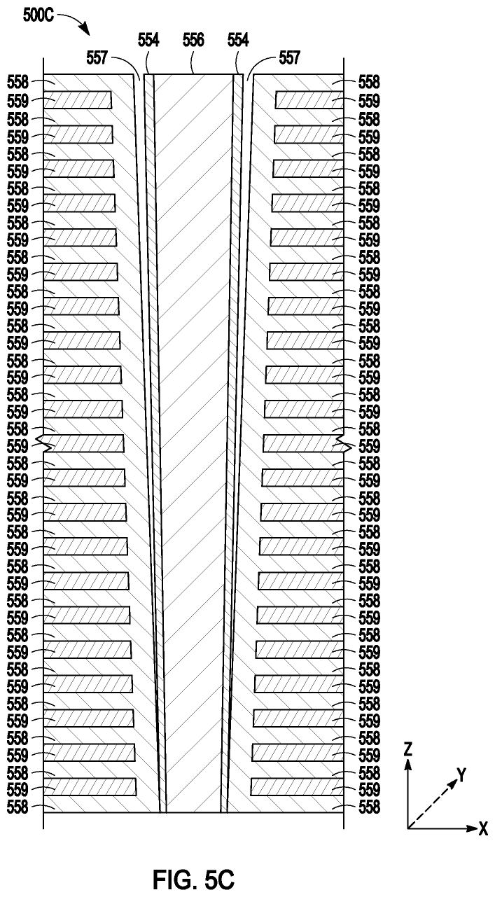

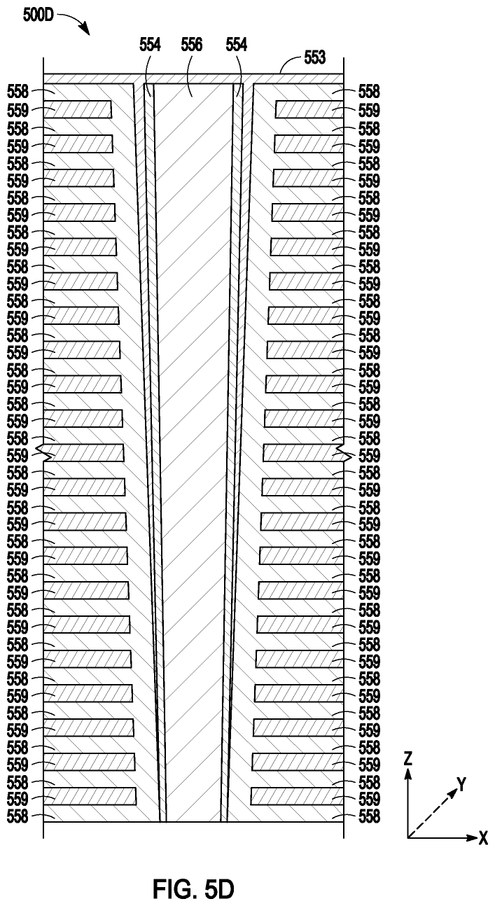

FIGS. 5A-5D is a representation of another embodiment of an example process flow of forming a metal contact in formation of a memory device, where the process flow is implemented to mitigate stress to the metal contact. FIG. 5A shows a structure 500A after an opening 551 has been formed in a region of alternating dielectric regions 559 and 558 in a vertical direction in fabrication of a memory device. The alternating dielectric regions 559 can be constructed as multiple dielectric regions 559, where the individual dielectric regions 559 of the multiple dielectric regions 559 are formed in parallel separated from each other by a dielectric region 558. Dielectric regions 559 form different levels in a vertical direction of structure 500A. In forming opening 551, the horizontal length of each individual dielectric region 559 can be larger than the horizontal lengths of dielectric region 559 above the individual dielectric region 559. The material of dielectric region 558 in structure 500A can be formed as walls of the opening 551. Alternatively, a material different from dielectric region 558 can be used to form the walls of opening 551. Dielectric regions 559 can be nitride regions, where the nitride can be, but is not limited to, silicon nitride. Dielectric regions 559 can be oxide regions, where the oxide can be, but is not limited to, silicon oxide.

A liner 552 has been formed on the walls of opening 551 in the dielectric defined by dielectric regions 558 and 559. Opening 551 extends through the levels, reflected in dielectric regions 559, for the memory device being fabricated. Liner 552 extends from a level at the top of opening 551 at least partially along the walls of opening 551. Liner 552 can be formed on the walls of opening 551 such that liner 552 does not extend to the bottom of opening 551 that is to be the bottom of the vertical metal contact being formed. The bottom of opening 551 is on a structure of the memory device being formed. An ex-situ or in-situ cleaning procedure can be used to remove any small amount at the bottom of opening 551 formed in the deposition of liner 552. Liner 552 can be a carbon liner. The carbon liner can be formed using a deposition process appropriate for forming a carbon liner to meet the structural dimensions for forming liner 552 in opening 551 to form a vertical metal contact for the memory device.

FIG. 5B shows a structure 500B after processing structure 500A. A metal composition has been formed adjacent liner 552, where the metal composition fills opening 551 of structure 500A. The metal composition can include a metal barrier region 554 and a primary metal 556. Metal barrier region 554 can be formed on and contacting liner 552 and primary metal 556 can be formed on and contacting metal barrier region 554. The combination of metal barrier region 554 and primary metal 556 can extend beyond liner 552 along the wall of opening 551 of structure 500A to the bottom of opening 551 of structure 500A.

Metal barrier region 554 can be a region of one or more metallic materials. Metal barrier region 554 can include two metallic materials. For example, the two metallic regions can include a metal element and a compound of the metal element with a non-metal, where the compound is a metallic compound. Metal barrier region 554 can include, but is not limited to, Ti formed on liner 552 and TiNx formed on the Ti. Primary metal 556 can be, but is not limited to, W. Materials for the metal composition of metal barrier region 554 and primary metal 556 can be formed using an appropriate process for forming the metal composition. After forming the metal composition, the surface of structure 500B has been subjected to a CMP procedure.

FIG. 5C shows a structure 500C after processing structure 500B. Liner 552 of structure 500B has been completely removed. Complete removal may include a negligible residual amount associated with performing a complete removal of the liner. An opening 557 has been formed in the removal of liner 552. A resist strip process can be used to remove liner 552. Removing liner 552 can create a free metal structure with respect to stress, relaxing the contact material of the metal composition of metal barrier region 554 and primary metal 556. Liner 552 can have a composition correlated to the metal composition such that removal of liner 552 reduces stress on the metal composition. Liner 552 can be formed as a carbon liner with the primary metal 556 being tungsten and metal barrier region 554 being titanium and titanium nitride.

FIG. 5D shows a structure 500D after processing structure 500C. A dielectric 553 has been formed on the top of structure 500C. The deposition of dielectric 553 on the top of structure 500C can include dielectric 553 being deposited into opening 557, filling the opening 557 of structure 500C. The material of dielectric 553 can be the same as the material of dielectric region 558. The material of dielectric 553 can be an oxide, such as but not limited to silicon oxide. In a non-limiting example, the structure of the metal composition of structure 500D can be used as a metal contact in thru-vias 344-1 . . . 344-7 or conductive contacts 343-1, 343-2, and 343-3 in memory device 300 of FIG. 3 with dielectric regions 559 replaced with metal, such as W, for access lines to memory cells in pillars according to the structural architecture of memory device 300.

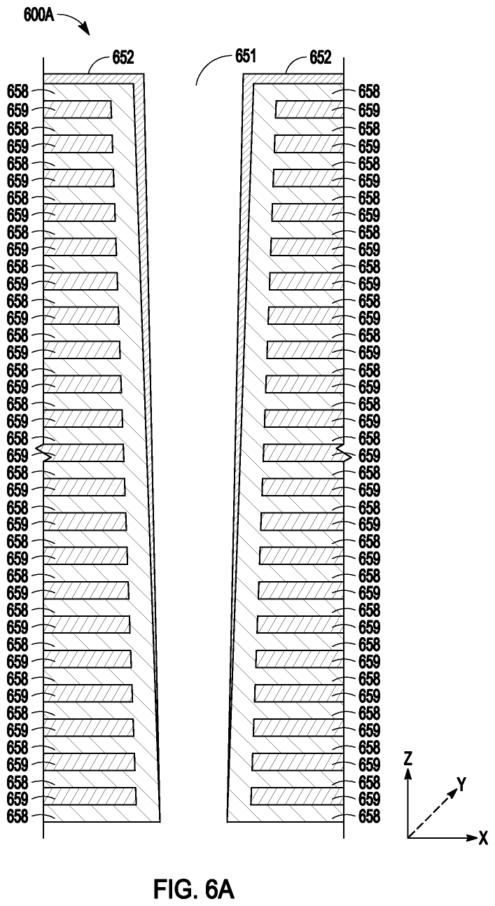

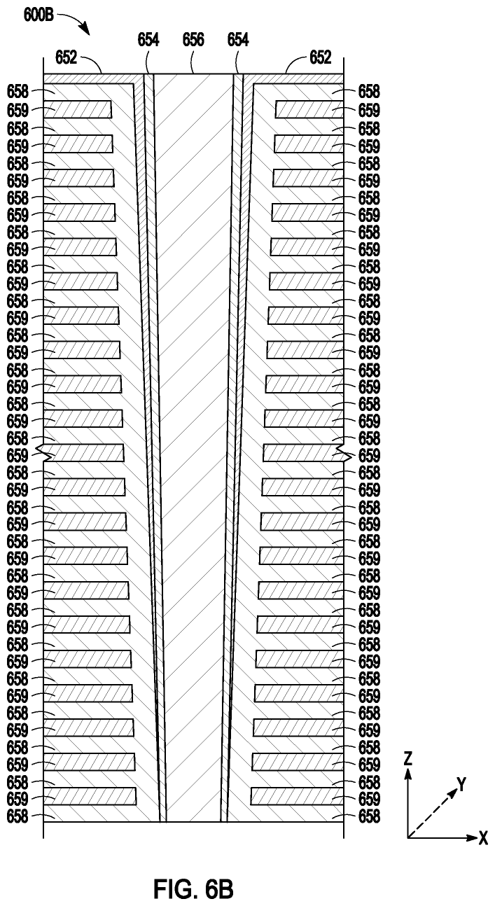

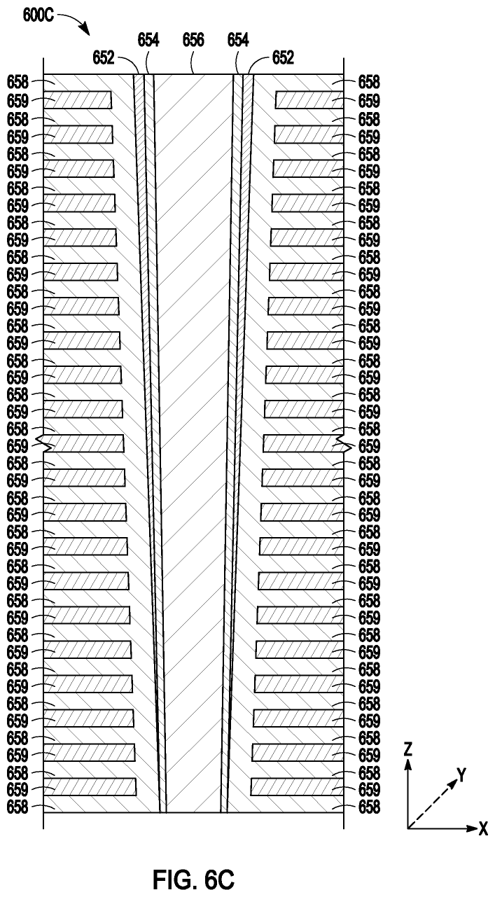

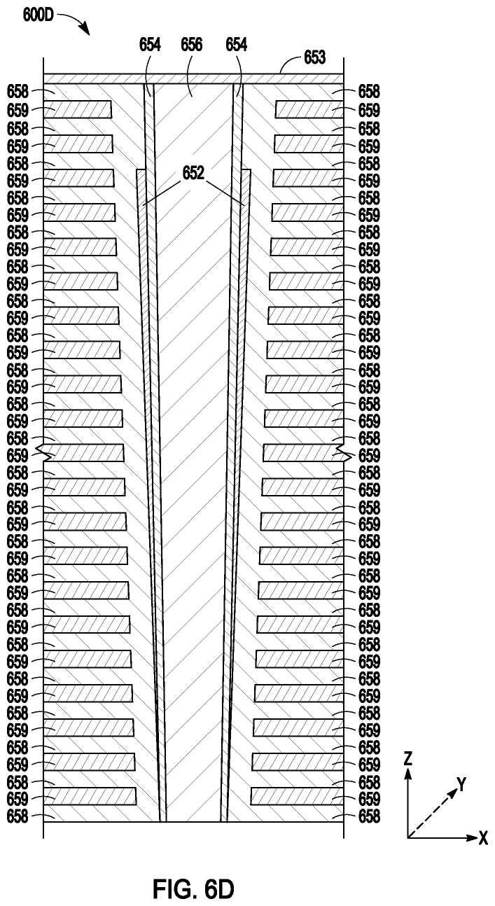

FIGS. 6A-6D is a representation of another embodiment of an example process flow of forming a metal contact in formation of a memory device, where the process flow is implemented to mitigate stress to the metal contact. FIG. 6A shows a structure 600A after an opening 651 has been formed in a region of alternating dielectric regions 659 and 658 in a vertical direction in fabrication of a memory device. The alternating dielectric regions 659 can be constructed as multiple dielectric regions 659, where the individual dielectric regions 659 of the multiple dielectric regions 659 are formed in parallel separated from each other by a dielectric region 658. Dielectric regions 659 form different levels in a vertical direction of structure 600A. In forming opening 651, the horizontal length of each individual dielectric region 659 can be larger than the horizontal lengths of dielectric region 659 above the individual dielectric region 659. The material of dielectric region 658 in structure 600A can be formed as walls of the opening 651. Alternatively, a material different from dielectric region 658 can be used to form the walls of opening 651. Dielectric regions 659 can be nitride regions, where the nitride can be, but is not limited to, silicon nitride. Dielectric regions 659 can be oxide regions, where the oxide can be, but is not limited to, silicon oxide.

A liner 652 has been formed on the walls of opening 651 in the dielectric defined by dielectric regions 658 and 659. Opening 651 extends through the levels, reflected in dielectric regions 659, for the memory device being fabricated. Liner 652 extends from a level at the top of opening 651 at least partially along the walls of opening 651. Liner 652 can be formed on the walls of opening 651 such that liner 652 does not extend to the bottom of opening 651 that is to be the bottom of the vertical metal contact being formed. The bottom of opening 651 is on a structure of the memory device being formed. An ex-situ or in-situ cleaning procedure can be used to remove any small amount at the bottom of opening 651 formed in the deposition of liner 652. Liner 652 can be a carbon liner. The carbon liner can be formed using a deposition process appropriate for forming a carbon liner to meet the structural dimensions for forming liner 652 in opening 651 to form a vertical metal contact for the memory device.

FIG. 6B shows a structure 600B after processing structure 600A. A metal composition has been formed adjacent liner 652, where the metal composition fills opening 651 of structure 600A. The metal composition can include a metal barrier region 654 and a primary metal 656. Metal barrier region 654 can be formed on and contacting liner 652 and primary metal 656 can be formed on and contacting metal barrier region 654. The combination of metal barrier region 654 and primary metal 656 can extend beyond liner 652 along the wall of opening 651 of structure 600A to the bottom of opening 651 of structure 600A.

Metal barrier region 654 can be a region of one or more metallic materials. Metal barrier region 654 can include two metallic materials. For example, the two metallic regions can include a metal element and a compound of the metal element with a non-metal, where the compound is a metallic compound. Metal barrier region 654 can include, but is not limited to, Ti formed on liner 652 and TiNx formed on the Ti. Primary metal 656 can be, but is not limited to, W. Materials for the metal composition of metal barrier region 654 and primary metal 656 can be formed using an appropriate process for forming the metal composition. After forming the metal composition, the surface of structure 600B has been subjected to a CMP procedure.

FIG. 6C shows a structure 600C after processing structure 600B. Liner 652 of structure 600B has been completely removed from the top of structure 600C. Complete removal may include a negligible residual amount associated with performing a complete removal of the liner from the top of structure 600B. Liner 652 of structure 600B can be removed from the top of structure 600B by a CMP procedure. Though liner 652 has been removed from the top of structure 600C, liner 652 is maintained between metal barrier region 654 and the dielectric forming the wall of opening 651 of FIG. 6A. Leaving the portion of liner 652 can allow the primary metal 656 to shrink by delaminating, which can create an airgap. Liner 652 can have a composition correlated to the metal composition such that liner 652 reduces stress on the metal composition. Liner 652 can be formed as a carbon liner with the primary metal 656 being tungsten and metal barrier region 654 being titanium and titanium nitride.

FIG. 6D shows a structure 600D after processing structure 600C. A portion of liner 652 has been removed from the top of structure 600C to a lower position along the length of metal barrier region 654. A dielectric 653 has been formed on the top of structure 600C and in the region from which the portion of liner 652 has been removed from the top of structure 600C to a lower position along the length of metal barrier region 654. The material of dielectric 653 can be the same as the material of dielectric region 658. The material of dielectric 653 can be an oxide, such as but not limited to silicon oxide. In a non-limiting example, the structure of the metal composition of structure 600D can be used as a metal contact in thru-vias 344-1 . . . 344-7 or conductive contacts 343-1, 343-2, and 343-3 in FIG. 3 with dielectric regions 659 replaced with metal, such as W, for access lines to memory cells in pillars according to the structural architecture of memory device 300.

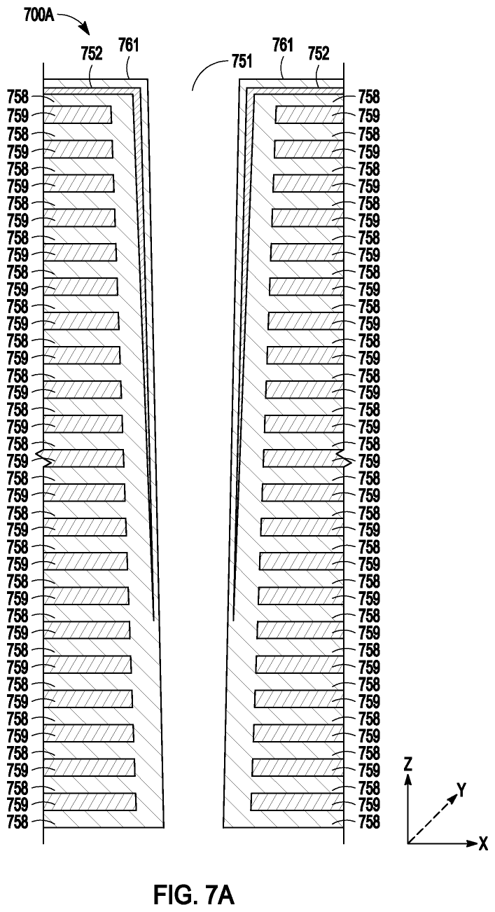

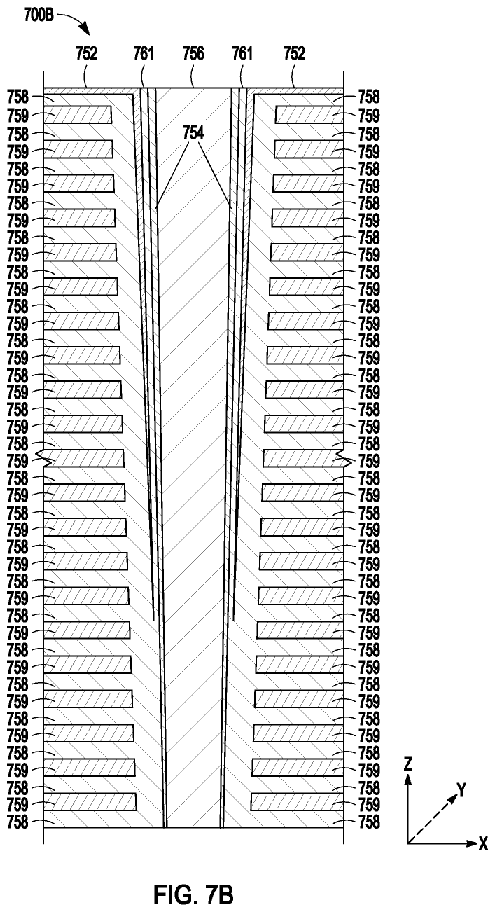

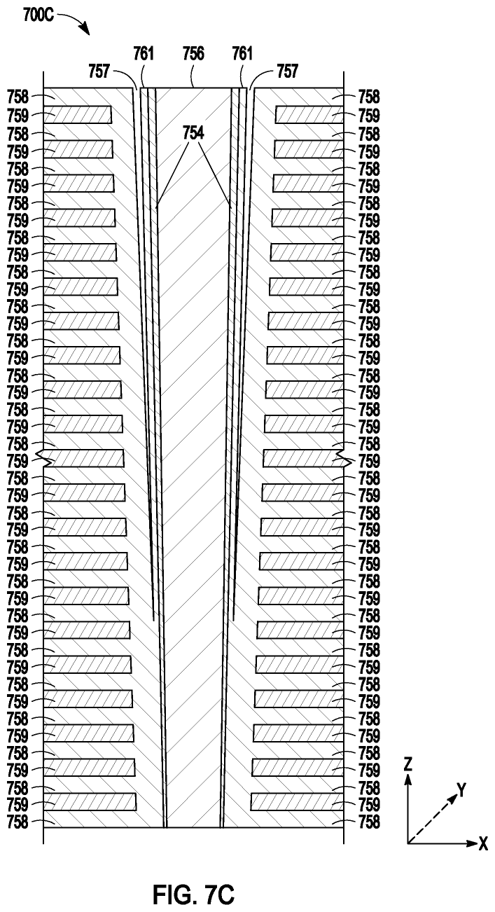

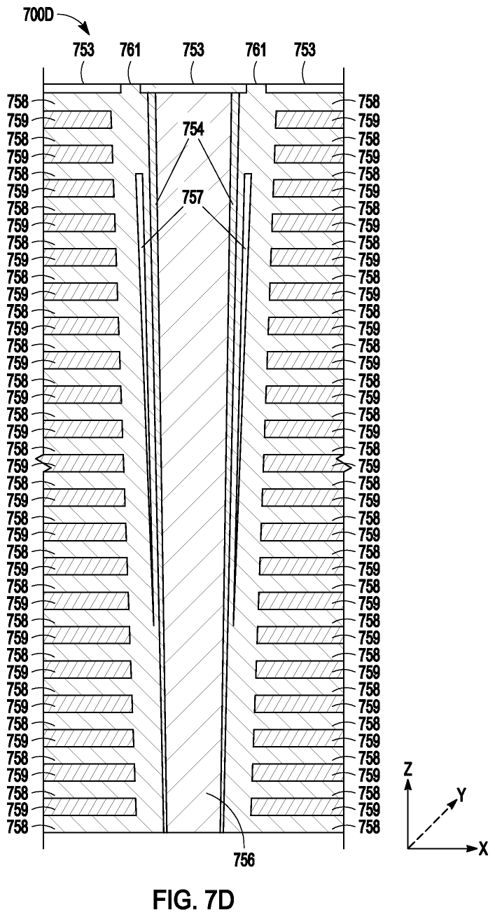

FIGS. 7A-7D is a representation of another embodiment of an example process flow of forming a metal contact in formation of a memory device, where the process flow is implemented to mitigate stress to the metal contact. FIG. 7A shows a structure 700A after an opening 751 has been formed in a region of alternating dielectric regions 759 and 758 in a vertical direction in fabrication of a memory device. The alternating dielectric regions 759 can be constructed as multiple dielectric regions 759, where the individual dielectric regions 759 of the multiple dielectric regions 759 are formed in parallel separated from each other by a dielectric region 758. Dielectric regions 759 form different levels in a vertical direction of structure 700A. In forming opening 751, the horizontal length of each individual dielectric region 759 can be larger than the horizontal lengths of dielectric region 759 above the individual dielectric region 759. The material of dielectric region 758 in structure 700A can be formed as walls of the opening 751. Alternatively, a material different from dielectric region 758 can be used to form the walls of opening 751. Dielectric regions 759 can be nitride regions, where the nitride can be, but is not limited to, silicon nitride. Dielectric regions 759 can be oxide regions, where the oxide can be, but is not limited to, silicon oxide.

A liner 752 has been formed on the walls of opening 751 in the dielectric defined by dielectric regions 758 and 759. Opening 751 extends through the levels, reflected in dielectric regions 759, for the memory device being fabricated. Liner 752 extends from a level at the top of opening 751 at least partially along the walls of opening 751. Liner 752 can be formed on the walls of opening 751 such that liner 752 does not extend to the bottom of opening 751 that is to be the bottom of the vertical metal contact being formed. The bottom of opening 751 is on a structure of the memory device being formed. An ex-situ or in-situ cleaning procedure can be used to remove any small amount at the bottom of opening 751 formed in the deposition of liner 752. Liner 752 can be a carbon liner. The carbon liner can be formed using a deposition process appropriate for forming a carbon liner to meet the structural dimensions for forming liner 752 in opening 751 to form a vertical metal contact for the memory device. A dielectric 761 can be formed on liner 752. The material of dielectric 761 can be the same as the material forming the wall of the opening 751. The material of dielectric 761 can be an oxide, such as but not limited to silicon oxide.

FIG. 7B shows a structure 700B after processing structure 700A. A metal composition has been formed on dielectric 761 adjacent liner 752, where the metal composition fills opening 751 of structure 700A. The metal composition can include a metal barrier region 754 and a primary metal 756. Metal barrier region 754 can be formed on and contacting dielectric 761 and primary metal 756 can be formed on and contacting metal barrier region 754. The combination of metal barrier region 754 and primary metal 756 can extend beyond liner 752 along the wall of opening 751 of structure 700A to the bottom of opening 751 of structure 700A.

Metal barrier region 754 can be a region of one or more metallic materials. Metal barrier region 754 can include two metallic materials. For example, the two metallic regions can include a metal element and a compound of the metal element with a non-metal, where the compound is a metallic compound. Metal barrier region 754 can include, but is not limited to, Ti formed on dielectric 761 and TiNx formed on the Ti. Primary metal 756 can be, but is not limited to, W. Materials for the metal composition of metal barrier region 754 and primary metal 756 can be formed using an appropriate process for forming the metal composition. After forming the metal composition, the surface of structure 700B has been subjected to a CMP procedure.

FIG. 7C shows a structure 700C after processing structure 700B. Liner 752 of structure 700B has been completely removed. Complete removal may include a negligible residual amount associated with performing a complete removal of the liner. An opening 757 has been formed in the removal of liner 752 between dielectric 761 and the wall of the opening 751 of structure 700A. A resist strip process can be used to remove liner 752, while substantially retaining dielectric 761. Removing liner 752 can create a free metal structure with respect to stress, relaxing the contact material of the metal composition of metal barrier region 754 and primary metal 756. Liner 752 can have a composition correlated to the metal composition such that removal of liner 752 reduces stress on the metal composition. Liner 752 can be formed as a carbon liner with the primary metal 756 being tungsten and metal barrier region 754 being titanium and titanium nitride.

FIG. 7D shows a structure 700D after processing structure 700C. A portion of opening 757 has been filled from the top of structure 700C to a lower position along the length of metal barrier region 754, leaving a portion of opening 757 as a void. A dielectric 753 has been formed on the top of structure 700C and in the portion of opening 757 from the top of structure 700C to the lower position along the length of metal barrier region 754. The material of dielectric 753 can be the same as the material of dielectric region 758. The material of dielectric 753 can be an oxide, such as but not limited to silicon oxide. In a non-limiting example, the structure of the metal composition of structure 700D can be used as a metal contact in thru-vias 344-1 . . . 344-7 or conductive contacts 343-1, 343-2, and 343-3 in memory device 300 of FIG. 3 with dielectric regions 759 replaced with metal, such as W, for access lines to memory cells in pillars according to the structural architecture of memory device 300.

Various deposition techniques for components of structures 400A-700D in the process flow of FIGS. 4A-7D can be used that are typical for the material being formed, the dimensions of the material being formed, and the architecture in which the material is being formed. Processes for forming the various materials can include, but are not limited to, chemical vapor deposition (CVD), atomic layer deposition (ALD), and physical vapor deposition (PVD). PVD can include, but is not limited to, sputtering, ion beam deposition, electron beam evaporation, pulsed laser deposition, and vacuum arc methods, among others. CVD can include, but is not limited to, plasma chemical vapor deposition and laser chemical vapor deposition, among others. Selective etching and conventional masking techniques can be used to remove selected regions in the processing discussed with respect to FIGS. 4A-7D. Etching procedures can include, but are not limited to, wet etching, dry etching, and atomic layer etching deposition, among others.

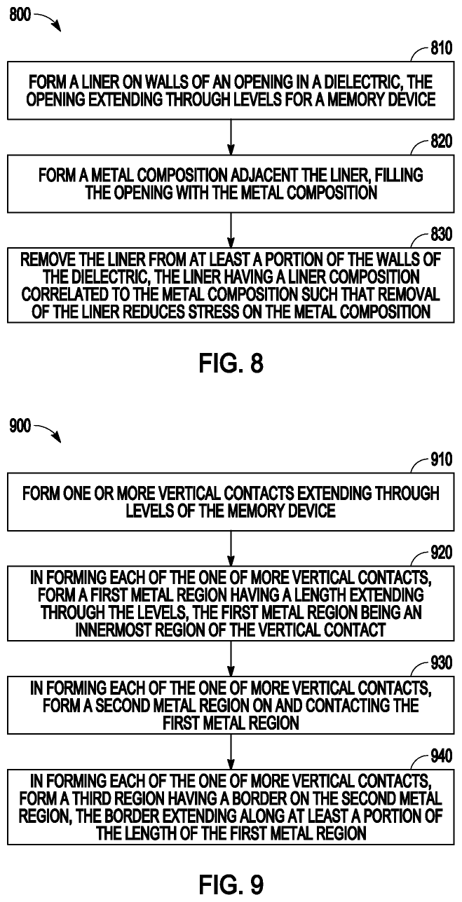

FIG. 8 is a flow diagram of features of an embodiment of an example method 800 of forming a vertical contact extending through levels of a memory device. At 810, a liner is formed on walls of an opening in a dielectric, where the opening extends through levels for the memory device. The dielectric can include, but is not limited to, an oxide. In addition, the oxide can include, but is not limited to, silicon oxide. At 820, a metal composition is formed adjacent the liner. The opening is filled with the metal composition. The metal composition can be formed contacting the liner or separated from the liner by a thin insulating material such as the material of the dielectric in which the opening is formed.

At 830, the liner is removed from at least a portion of the walls of the dielectric. The liner has a liner composition correlated to the metal composition such that removal of the liner reduces stress on the metal composition. If a thin insulating material is used in the procedure before the liner removal, the thin insulating material is thin relative to a thickness that does not inhibit the process of forming the vertical contact that mitigates stress on the vertical contact. The thin insulating material can be deposited on the liner with some thickness loss, which can be compensated at the liner removal procedure. The selections of the materials for the liner, the metal composition, and various dielectrics in the region of the vertical contact are made to mitigate stress on the vertical contact in the procedures for forming such vertical contacts.

Variations of method 800 or methods similar to method 800 can include a number of different embodiments that can be combined depending on the application of such methods and/or the architecture of systems in which such methods are implemented. Such methods can include forming the vertical contact to extend from a level above a memory array region for the memory device to a level below the memory array region. The vertical contact can be one of a number of vertical contacts formed in the same manner. Such multiple vertical contacts can be formed in the same process flow.

Variations of method 800 or methods similar to method 800 can include the metal composition having a primary metal with a metal barrier region positioned on the primary metal, where the metal barrier region defines an outer border of the metal contact. The metal barrier region can be a multiple metallic region. The multiple metallic region can include two metallic materials. For example, the two metallic regions can include a metal element and a compound of the metal element with a non-metal, where the compound is a metallic compound. Variations can include maintaining a void in a portion of a region from which the liner is removed or leaving a portion of the liner on a portion of the walls of the dielectric.

FIG. 9 is a flow diagram of features of an embodiment of another example method 900 of forming a memory device. At 910, one or more vertical contacts are formed extending through levels for a memory device. The one or more vertical contacts can extend from above a memory array of the memory device to below the memory array. The region below the memory array to which the vertical contacts extend can be a CUA region of a memory device. In other architectures for a memory device, the one or more vertical contacts can extend from above a memory array of the memory device to a level corresponding to the bottom of a memory array.

At 920, in forming each of the one or more vertical contacts, a first metal region is formed having a length extending through the levels. The first metal region is being formed as an innermost region of the vertical contact. The first metal region can include tungsten. At 930, in forming each of the one or more vertical contacts, a second metal region is formed on and contacting the first metal region. The second metal region can include titanium, titanium nitride, or a combination of titanium and titanium nitride.

At 930, in forming each of the one or more vertical contacts, a third region is formed having a border on the second metal region, where the border extends along at least a portion of the length of the first metal region. The third region can be structured with various different formats. The third region can include a void. The third region can include carbon. The third region can include a void separated from the border by a dielectric material. The third region can include a dielectric region between the second metal region and a wall of a dielectric structure in which the vertical contact is positioned.

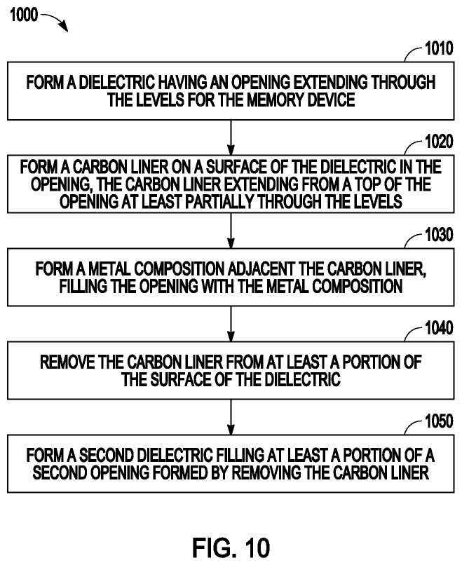

FIG. 10 is a flow diagram of features of an embodiment of another example method 1000 of forming a vertical contact extending through levels of a memory device. At 1010, a dielectric is formed having an opening extending through the levels for the memory device. At 1020, a carbon liner is formed on a surface of the dielectric in the opening, where the carbon liner extends from a top of the opening at least partially through the levels. At 1030, a metal composition is formed adjacent the carbon liner, filling the opening with the metal composition. At 1040, the carbon liner is removed from at least a portion of the surface of the dielectric. At 1050, a second dielectric is formed filling at least a portion of a second opening formed by removing the carbon liner.

Variations of method 1000 or methods similar to method 1000 can include a number of different embodiments that can be combined depending on the application of such methods and/or the architecture of systems in which such methods are implemented. Such methods can include forming the metal composition to include Ti/TiN/W. The Ti can be formed on the carbon liner. The titanium can extend through the levels in the opening to form an outer boundary of the vertical contact, though the carbon liner is not formed along the entire length of the opening formed to fabricate the vertical contact. TiN can be formed on the titanium and W can be formed on the titanium nitride, filling the opening to form a Ti/TiN/W metal contact. In the Ti/TiN/W metal contact, W can be the primary metal.

Variations of method 1000 or methods similar to method 1000 can include different procedures in the mechanism of removing the carbon. The variations can include completely removing the carbon liner from the surface of the dielectric. After the removal of the carbon layer, the second dielectric can be formed by atomic layer deposition, completely filling the second opening with the second dielectric. The variations can include maintaining a void in the second opening when filling at least a portion of the second opening. Variations can include forming a third dielectric on the carbon liner before forming the metal composition. Other variations of removing the carbon liner can include leaving a portion of the carbon liner on a portion of the surface of the dielectric. The portion of the carbon liner remaining can be an amount that is more than a negligible residual amount associated with performing a complete removal of the carbon liner.

Electronic devices, such as mobile electronic devices (e.g., smart phones, tablets, etc.), electronic devices for use in automotive applications (e.g., automotive sensors, control units, driver-assistance systems, passenger safety or comfort systems, etc.), and internet-connected appliances or devices (e.g., Internet-of-Things (IoT) devices, etc.), have varying storage needs depending on, among other things, the type of electronic device, use environment, performance expectations, etc. Electronic devices can be broken down into several main components: a processor (e.g., a central processing unit (CPU) or other main processor); memory (e.g., one or more volatile or non-volatile RAM memory device, such as DRAM, mobile or low-power double-data-rate synchronous DRAM (DDR SDRAM), etc.); and a storage device (e.g., non-volatile memory (NVM) device, such as flash memory, ROM, a solid-state drive (SSD), a MultiMediaCard (MMC), or other memory card structure or assembly, etc.). In certain examples, electronic devices can include a user interface (e.g., a display, touch-screen, keyboard, one or more buttons, etc.), a graphics processing unit (GPU), a power management circuit, a baseband processor or one or more transceiver circuits, etc.

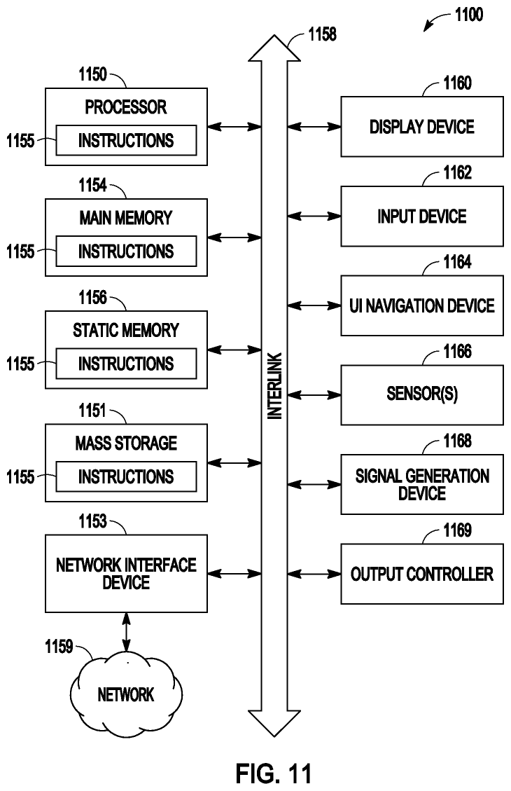

FIG. 11 illustrates a block diagram of an example machine 1100 having one or more memory devices, where each of these memory devices include one or more vertical metal contacts implemented to mitigate stress to the one or more vertical metal contacts. Such memory devices can include a memory array extending over a substrate, with the memory array including multiple vertically arranged tiers comprising memory cells. Machine 1100, having one or more such memory devices, may operate as a standalone machine or may be connected, for example networked, to other machines.

In a networked deployment, machine 1100 may operate in the capacity of a server machine, a client machine, or both in server-client network environments. In an example, machine 1100 may act as a peer machine in peer-to-peer (P2P) (or other distributed) network environment. Machine 1100 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more methodologies, such as cloud computing, software as a service (SaaS), or other computer cluster configurations. The example machine 1100 can be arranged to operate with one or more memory devices having a CuA architecture such as but not limited to the example memory device 200 of FIG. 2 or memory device 300 of FIG. 3. The example machine 1100 can include one or more memory devices functionally structured similar to memory device 100 of FIG. 1.

Examples, as described herein, may include, or may operate by logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to store instructions of the specific operation. In connecting the physical components, the underlying electrical properties of a hardware constituent may be changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry, at a different time.

The machine 1100 may include a hardware processor 1150 (e.g., a CPU, a GPU, a hardware processor core, or any combination thereof), a main memory 1154, and a static memory 1156, some or all of which may communicate with each other via an interlink 1158 (e.g., bus). Machine 1100 may further include a display device 1160, an input device 1162, which can be an alphanumeric input device (e.g., a keyboard), and a user interface (UI) navigation device 1164 (e.g., a mouse). In an example, display device 1160, input device 1162, and UI navigation device 1164 may be a touch screen display. Machine 1100 may additionally include a mass storage device (e.g., drive unit) 1151, a network interface device 1153, a signal generation device 1168, and one or more sensors 1166, such as a global positioning system (GPS) sensor, compass, accelerometer, or other sensor. Machine 1100 may include an output controller 1169, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

Machine 1100 may include one or more machine-readable media on which is stored one or more sets of data structures or instructions 1155 (e.g., software, microcode, or other type of instructions) embodying or utilized by machine 1100 to perform any one or more of the techniques or functions for which machine 1100 is designed. The instructions 1155 may reside, completely or at least partially, within main memory 1154, within static memory 1156, or within hardware processor 1150 during execution thereof by machine 1100. In an example, one or any combination of hardware processor 1150, main memory 1154, static memory 1156, or mass storage device 1151 may constitute the machine-readable media on which is stored one or more sets of data structures or instructions.

While an example machine-readable medium is illustrated as a single medium, the term “machine-readable medium” may include a single medium or multiple media (e.g., a centralized or distributed database, or associated caches and servers) configured to store instructions 1155 or data. The term “machine-readable medium” may include any medium that is capable of storing instructions for execution by machine 1100 and that cause machine 1100 to perform any one or more of the techniques to which machine 1100 is designed, or that is capable of storing data structures used by or associated with such instructions. Non-limiting machine-readable medium examples may include solid-state memories, optical media, and magnetic media. Specific examples of non-transitory machine-readable media may include: non-volatile memory, such as semiconductor memory devices (e.g., EPROM, EEPROM) and flash memory devices; magnetic disks, such as internal hard disks and removable disks; magneto-optical disks; and compact disc-ROM (CD-ROM) and digital versatile disc-read only memory (DVD-ROM) disks.

Instructions 1155 (e.g., software, programs, an operating system (OS), etc.) or other data stored on mass storage device 1151 can be accessed by main memory 1154 for use by hardware processor 1150. Main memory 1154 (e.g., DRAM) is typically fast, but volatile, and thus a different type of storage than mass storage device 1151 (e.g., an SSD), which is suitable for long-term storage, including while in an “off” condition. Instructions 1155 or data in use by a user or machine 1100 are typically loaded in main memory 1154 for use by hardware processor 1150. When main memory 1154 is full, virtual space from mass storage device 1151 can be allocated to supplement main memory 1154; however, because mass storage device 1151 is typically slower than main memory 1154, and write speeds are typically at least twice as slow as read speeds, use of virtual memory can greatly reduce user experience due to storage device latency (in contrast to main memory 1154, e.g., DRAM). Further, use of mass storage device 1151 for virtual memory can greatly reduce the usable lifespan of mass storage device 1151.

Storage devices optimized for mobile electronic devices, or mobile storage, traditionally include MMC solid-state storage devices (e.g., micro Secure Digital (microSD™) cards, etc.). MMC devices include a number of parallel interfaces (e.g., an 8-bit parallel interface) with a host device and are often removable and separate components from the host device. In contrast, embedded MMC (eMMC™) devices are attached to a circuit board and considered a component of the host device, with read speeds that rival Serial Advanced Technology Attachment (SATA)-based SSD devices. However, demand for mobile device performance continues to increase, such as to fully enable virtual or augmented-reality devices, utilize increasing networks speeds, etc. In response to this demand, storage devices have shifted from parallel to serial communication interfaces. Universal Flash Storage (UFS) devices, including controllers and firmware, communicate with a host device using a low-voltage differential signaling (LVDS) serial interface with dedicated read/write paths, further advancing greater read/write speeds.

Instructions 1155 may further be transmitted or received over a network 1159 using a transmission medium via signal generation device 1168 or network interface device 1153 utilizing any one of a number of transfer protocols (e.g., frame relay, Internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, peer-to-peer (P2P) networks, among others. In an example, signal generation device 1168 or network interface device 1153 may include one or more physical jacks (e.g., Ethernet, coaxial, or phone jacks) or one or more antennas to connect to network 1159. In an example, signal generation device 1168 or network interface device 1153 may include a plurality of antennas to wirelessly communicate using at least one of single-input multiple-output (SIMO), multiple-input multiple-output (MIMO), or multiple-input single-output (MISO) techniques. The term “transmission medium” shall be taken to include any tangible medium that is capable of carrying instructions to and for execution by machine 1100 or data to or from machine 1100, and includes instrumentalities to propagate digital or analog communications signals to facilitate communication of such instructions, which instructions may be implemented by software or data.

The following are example embodiments of devices and methods, in accordance with the teachings herein.

An example method 1 of forming a vertical contact extending through levels of a memory device can comprise forming a liner on walls of an opening in a dielectric, the opening extending through the levels for the memory device; forming a metal composition adjacent the liner, filling the opening with the metal composition; and removing the liner from at least a portion of the walls of the dielectric, the liner having a liner composition correlated to the metal composition such that removal of the liner reduces stress on the metal composition.

An example method 2 of forming a vertical contact extending through levels of a memory device can include features of example method 1 of forming a vertical contact extending through levels of a memory device and can include forming the vertical contact to extend from a level above a memory array region for the memory device to a level below the memory array region.

An example method 3 of forming a vertical contact extending through levels of a memory device can include features of example method 2 of forming a vertical contact extending through levels of a memory device and any of the preceding example method 1 of forming a vertical contact extending through levels of a memory device and can include the metal composition including a primary metal with a metal barrier region positioned on the primary metal, the metal barrier region defining an outer border of the metal contact.

An example method 4 of forming a vertical contact extending through levels of a memory device can include features of example method 3 of forming a vertical contact extending through levels of a memory device and any of the preceding example methods 1 to 2 of forming a vertical contact extending through levels of a memory device and can include the metal barrier region including two metallic materials.

An example method 5 of forming a vertical contact extending through levels of a memory device can include features of any of the preceding example methods 1 to 4 of forming a vertical contact extending through levels of a memory device and can include maintaining a void in a portion of a region from which the liner is removed or leaving a portion of the liner on a portion of the walls of the dielectric.

In an example method 6 of forming a vertical contact extending through levels of a memory device, any of the example methods 1 to 5 of forming a vertical contact extending through levels of a memory device may be performed in forming an electronic memory apparatus further comprising a host processor and a communication bus extending between the host processor and the memory device.

In an example method 7 of forming a vertical contact extending through levels of a memory device, any of the example methods 1 to 6 of forming a vertical contact extending through levels of a memory device may be modified to include operations set forth in any other of example methods 1 to 6 of forming a vertical contact extending through levels of a memory device.

In an example method 8 of forming a vertical contact extending through levels of a memory device, any of the example methods 1 to 7 of forming a vertical contact extending through levels of a memory device may be implemented at least in part through use of instructions stored as a physical state in one or more machine-readable storage devices.

An example method 9 of forming a vertical contact extending through levels of a memory device can include features of any of the preceding example methods 1 to 8 of forming a vertical contact extending through levels of a memory device and can include performing functions associated with any features of example memory devices 1 to 12.

An example method 10 of forming a vertical contact extending through levels of a memory device can comprise: forming a dielectric having an opening extending through the levels for the memory device; forming a carbon liner on a surface of the dielectric in the opening, the carbon liner extending from a top of the opening at least partially through the levels; forming a metal composition adjacent the carbon liner, filling the opening with the metal composition; and removing the carbon liner from at least a portion of the surface of the dielectric; and forming a second dielectric filling at least a portion of a second opening formed by removing the carbon liner.

An example method 11 of forming a vertical contact extending through levels of a memory device can include features of example method 10 of forming a vertical contact extending through levels of a memory device and can include forming the metal composition to include: forming titanium on the carbon liner, the titanium extending through the levels in the opening; forming titanium nitride on the titanium; and forming tungsten on the titanium nitride, filling the opening.

An example method 12 of forming a vertical contact extending through levels of a memory device can include features of any of the preceding example methods 10 and 11 of forming a vertical contact extending through levels of a memory device and can include completely removing the carbon liner from the surface of the dielectric.

An example method 13 of forming a vertical contact extending through levels of a memory device can include features of example method 12 of forming a vertical contact extending through levels of a memory device and any of the preceding example methods 10 and 11 of forming a vertical contact extending through levels of a memory device and can include forming the second dielectric by atomic layer deposition, completely filling the second opening with the second dielectric.

An example method 14 of forming a vertical contact extending through levels of a memory device can include features of example method 12 of forming a vertical contact extending through levels of a memory device and any of the preceding example methods 10, 11, and 13 of forming a vertical contact extending through levels of a memory device and can include filling at least a portion of a second opening to include maintaining a void in the second opening.

An example method 15 of forming a vertical contact extending through levels of a memory device can include features of example method 14 of forming a vertical contact extending through levels of a memory device and any of the preceding example methods 10 to 13 of forming a vertical contact extending through levels of a memory device and can include forming a third dielectric on the carbon liner before forming the metal composition.

An example method 16 of forming a vertical contact extending through levels of a memory device can include features of any of the preceding example methods 10 to 15 of forming a vertical contact extending through levels of a memory device and can include removing the carbon liner to include leaving a portion of the carbon liner on a portion of the surface of the dielectric.

In an example method 17 of forming a vertical contact extending through levels of a memory device, any of the example methods 10 to 16 of forming a vertical contact extending through levels of a memory device may be performed in forming an electronic memory apparatus further comprising a host processor and a communication bus extending between the host processor and the memory device.

In an example method 18 of forming a vertical contact extending through levels of a memory device, any of the example methods 1 to 17 of forming a vertical contact extending through levels of a memory device may be modified to include operations set forth in any other of methods 1 to 17 of forming a vertical contact extending through levels of a memory device example.

In an example method 19 of forming a vertical contact extending through levels of a memory device, any of the example methods 10 to 18 of forming a vertical contact extending through levels of a memory device may be implemented at least in part through use of instructions stored as a physical state in one or more machine-readable storage devices.

An example method 20 of forming a vertical contact extending through levels of a memory device can include features of any of the preceding example methods 10 to 19 of forming a vertical contact extending through levels of a memory device and can include performing functions associated with any features of example memory devices 1 to 12.

An example memory device 1 can comprise: one or more vertical contacts extending through levels of the memory device, each of the one or more vertical contacts including: a first metal region having a length extending through the levels, the first metal region being an innermost region of the vertical contact; a second metal region on and contacting the first metal region; and a third region having a border on the second metal region, the border extending along at least a portion of the length of the first metal region.

An example memory device 2 can include features of example memory device 1 and can include the one or more vertical contacts extending from above a memory array of the memory device to below the memory array.

An example memory device 3 can include features of any features of the preceding example memory devices and can include the third region including a void.

An example memory device 4 can include features of any of the preceding example memory devices and can include the third region including carbon.

An example memory device 5 can include features of any features of the preceding example memory devices and can include the third region including a void separated from the border by a dielectric material.

An example memory device 6 can include features of any of the preceding example memory devices and can include the third region having a dielectric region between the second metal region and a wall of a dielectric structure in which the vertical contact is positioned.

An example memory device 7 can include features of any of the preceding example memory devices and can include the first metal region including tungsten.

An example memory device 8 can include features of any of the preceding example memory devices and can include the second metal region including titanium, titanium nitride, or a combination of titanium and titanium nitride.

In an example memory device 9, any of the memory devices of example memory devices 1 to 8 may include memory devices incorporated into an electronic memory apparatus further comprising a host processor and a communication bus extending between the host processor and the memory device.

In an example memory device 10, any of the memory devices of example memory devices 1 to 9 may be modified to include any structure presented in another of example memory device 1 to 9.

In an example memory device 11, any apparatus associated with the memory devices of example memory devices 1 to 10 may further include a machine-readable storage device configured to store instructions as a physical state, wherein the instructions may be used to perform one or more operations of the apparatus.

In an example memory device 12, any of the memory devices of example memory devices 1 to 11 may be operated in accordance with any of the methods of forming a vertical contact extending through levels of a memory device of the example methods 1 to 20 of forming a vertical contact extending through levels of a memory device.

An example machine-readable storage device 1 storing instructions, that when executed by one or more processors, cause a machine to perform operations, can comprise instructions to perform functions associated with any features of example memory devices 1 to 12 or perform methods associated with any features of example methods 1 to 20.

Although specific embodiments have been illustrated and described herein, it will be appreciated by those of ordinary skill in the art that any arrangement that is calculated to achieve the same purpose may be substituted for the specific embodiments shown. Various embodiments use permutations and/or combinations of embodiments described herein. It is to be understood that the above description is intended to be illustrative, and not restrictive, and that the phraseology or terminology employed herein is for the purpose of description.

What is claimed is:

1. A method of forming a vertical contact extending through levels of a memory device, the method comprising:
forming a liner on walls of an opening in a dielectric, the opening extending through the levels for the memory device;
forming a metal composition adjacent the liner, filling the opening with the metal composition; and
removing the liner from at least a portion of the walls of the dielectric, the liner having a liner composition correlated to the metal composition such that removal of the liner reduces stress on the metal composition.

2. The method of claim 1, wherein the method includes forming the vertical contact to extend from a level above a memory array region for the memory device to a level below the memory array region.

3. The method of claim 2, wherein the metal composition includes a primary metal with a metal barrier region positioned on the primary metal, the metal barrier region defining an outer border of the metal contact.

4. The method of claim 3, wherein the metal barrier region includes two metallic materials.

5. The method of claim 1, wherein the method includes maintaining a void in a portion of a region from which the liner is removed or leaving a portion of the liner on a portion of the walls of the dielectric.

6. A method of forming a vertical contact extending through levels of a memory device, the method comprising:
forming a dielectric having an opening extending through the levels for the memory device;
forming a carbon liner on a surface of the dielectric in the opening, the carbon liner extending from a top of the opening at least partially through the levels;
forming a metal composition adjacent the carbon liner, filling the opening with the metal composition;
removing the carbon liner from at least a portion of the surface of the dielectric; and
forming a second dielectric filling at least a portion of a second opening formed by removing the carbon liner.

7. The method of claim 6, wherein forming the metal composition includes:
forming titanium on the carbon liner, the titanium extending through the levels in the opening;
forming titanium nitride on the titanium; and
forming tungsten on the titanium nitride, filling the opening.

8. The method of claim 7, wherein the method includes completely removing the carbon liner from the surface of the dielectric.

9. The method of claim 8, wherein the method includes forming the second dielectric by atomic layer deposition, completely filling the second opening with the second dielectric.

10. The method of claim 8, wherein filling at least a portion of the second opening includes maintaining a void in the second opening.

11. The method of claim 10, wherein the method includes forming a third dielectric on the carbon liner before forming the metal composition.

12. The method of claim 7, wherein removing the carbon liner includes leaving a portion of the carbon liner on a portion of the surface of the dielectric.

13. A memory device comprising:
one or more vertical contacts extending through levels of the memory device, each of the one or more vertical contacts including:
a first metal region having a length extending through the levels, the first metal region being an innermost region of the vertical contact;
a second metal region on and contacting the first metal region; and
a third region having a border on the second metal region, the border extending along at least a portion of the length of the first metal region.

14. The memory device of claim 13, wherein the one or more vertical contacts extend from above a memory array of the memory device to below the memory array.

15. The memory device of claim 13, wherein the third region includes a void.

16. The memory device of claim 13, wherein the third region includes carbon.

17. The memory device of claim 13, wherein the third region includes a void separated from the border by a dielectric material.

18. The memory device of claim 13, wherein the third region includes a dielectric region between the second metal region and a wall of a dielectric structure in which the vertical contact is positioned.

19. The memory device of claim 13, wherein the first metal region includes tungsten.

20. The memory device of claim 13, wherein the second metal region includes titanium, titanium nitride, or a combination of titanium and titanium nitride.
